(19) United States
(12) Patent Application Publication
(10) Pub. No.: US 2009/0215349 A1
(43) Pub. Date: Aug. 27, 2009

(54) METHOD FOR MANUFACTURING LIGHT-EMITTING DEVICE

(75) Inventor: Kazunori SAKURAI, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/368,639

(22) Filed: Feb. 10, 2009

(30) Foreign Application Priority Data
Feb. 21, 2008 (JP) 2008-039839

(51) Int. Cl. H01J 9/00

(52) U.S. Cl. 445/23

(57) ABSTRACT

A method for manufacturing a light-emitting device includes a first step of forming at least one light-emitting element on a first substrate; a second step of applying a resin adhesive to a first application area that includes an area where the at least one light-emitting element is formed, so as to cover the at least one light-emitting element; a third step of applying a glass frit paste on a surface of the first substrate where the at least one light-emitting element is formed or on a second substrate and also to a second application area that surrounds the area where the at least one light-emitting element is formed; a fourth step of laminating the first substrate and the second substrate; a resin curing step of curing the resin adhesive to bond the first substrate and the second substrate in the first application area and to seal the at least one light-emitting element from an outside; and a glass frit melting step of melting the glass frit paste to bond the first substrate and the second substrate in the second application area.

### BACKGROUND

1. Technical Field

The present invention relates to a method for manufacturing a light-emitting device that emits light by electroluminescence.

2. Related Art

Organic light emitting diodes (OLED), that is, organic electroluminescent (EL) elements are attracting attention as a lightweight thin light-emitting source. Such an organic EL element has a structure in which a pixel electrode and a counter electrode sandwich at least one layer of an organic thin film made of an organic material. The organic EL element emits light when a certain current is supplied between the pixel electrode and the counter electrode.

A light-emitting device including such organic EL elements is used for a printer head of an image-forming apparatus such as a tandem type line printer or a four-cycle type line printer. The image-forming apparatus includes an image carrier such as a photosensitive drum, a charging unit, a developing unit, and a transferring unit, in addition to the printer head. After the image carrier is charged with the charging unit, it is exposed to light emitted from the organic EL elements, which are part of the printer head. An electrostatic latent image is then formed on a surface of the image carrier by this exposure. Subsequently, the electrostatic latent image is developed with a toner supplied from the developing unit, and the toner is transferred to a transfer medium such as paper using the transferring unit, As a result, a desired image is formed on the transfer medium.

For example, the device disclosed in Japanese Unexamined Patent Application Publication No. 2002-280168 is known as a light-emitting device incorporated in such an image-forming apparatus or the like.

The organic EL elements included in the light-emitting device generate heat as a result of receiving the supply of a current as described above. The heat may adversely affect the physical form of the light-emitting device. Specifically, the light-emitting device includes an element substrate on which the organic EL elements or the like are formed, and the element substrate may become deformed (e.g., warped or distorted) due to the heat. This significantly affects precise forming of the electrostatic latent image.

Alternatively, each of the organic EL elements generally has a characteristic that its luminance changes in accordance with a temperature change. For example, as the organic EL element is heated by the heat generated therefrom, the luminance is changed compared with the case where the organic EL element is not heated. This is an obstacle to meeting demands such as maintaining the gradation of the image.

The organic EL element is sensitive to moisture. When moisture enters the organic EL element, detachment of the organic thin film and the pixel electrode or the counter electrode may occur, or the organic thin film itself, for example, may deteriorate. In the end, the organic EL element may lose its light-emitting ability. The practical problem is that the entry of moisture shortens the life of the organic EL element. Thus, the organic EL element should be protected from the entry of moisture to a maximum extent.

Japanese Unexamined Patent Application Publication No. 2002-280168 described above discloses one means for solving the problem related to moisture. Japanese Unexamined Patent Application Publication No. 2002-280168 discloses a technology for preventing the entry of moisture into “a layered structure” by including “a support substrate” where “the layered structure”, which is an organic EL element, is formed and “a sealing member” having “arrangement portions formed so as to face an area where the layered structure is not formed and adsorptive members with hygroscopicity arranged on the arrangement portions” (the text enclosed in quotation marks are from claim 1 of Japanese Unexamined Patent Application Publication No. 2002-280168; FIG. 1 or the like thereof can be referred to). However, the problem related to the heat described above is not treated in Japanese unexamined Patent Application Publication No. 2002-280168.

### SUMMARY

An advantage of some aspects of the invention is that it provides a method for manufacturing a light-emitting device that can suppress the effect of heat generated from a light-emitting element and can prevent the entry of moisture into the light-emitting element. Another advantage of some aspects of the invention is that it provides a method for manufacturing the light-emitting device in which the accompanying problems caused in achieving the advantage described above can be solved.

A method for manufacturing a light-emitting device according to an aspect of the invention includes a first step of forming at least one light-emitting element on a first substrate; a second step of applying a resin adhesive to a first application area that includes an area where the at least one light-emitting element is formed, so as to cover the at least one light-emitting element; a third step of applying a glass frit paste on a surface of the first substrate where the at least one light-emitting element is formed or on a second substrate and also to a second application area that surrounds the area where the at least one light-emitting element is formed; a fourth step of laminating the first substrate and the second substrate; a resin curing step of curing the resin adhesive to bond the first substrate and the second substrate in the first application area and to seal the at least one light-emitting element from an outside; and a glass frit melting step of melting the glass frit paste to bond the first substrate and the second substrate in the second application area.

In this aspect of the invention, the first substrate and the second substrate constituting a finished light-emitting device are bonded together using the resin adhesive and the glass frit. The light-emitting element is sealed within the cured resin adhesive. In this structure, the heat generated from the light-emitting element can be conducted through the first substrate while through the resin adhesive to the second substrate side.

The light-emitting element is protected from moisture, oxygen, or the like that exists outside, firstly by the glass frit extending so as to surround the area where the light-emitting element is formed and secondly by the resin adhesive. In particular, the glass frit according to the aspect of the invention exhibits an even higher effect of preventing the entry of moisture than the resin adhesive or the like.

In the light-emitting device manufactured by the method according to the aspect of the invention, the heat can be significantly effectively radiated and the entry of moisture or the like into the light-emitting element can be suppressed to a maximum extent.

The order of conducting the steps mentioned in this specification is not limited unless “after the first step” or the like (in the case of the aspect described above) is particularly mentioned. For example, the second step may be conducted before the third step and vice versa. Alternatively, for example, the glass frit paste and the resin adhesive may be respectively applied to the second substrate and the first substrate at the same time. However, the case where the order of the steps needs to be limited in view of the nature of each step is exceptional (e.g. the fourth step needs to be conducted after the first step in view of its nature).

In the method for manufacturing the light-emitting device according to an aspect of the invention, after the fourth step, the resin curing step may be conducted and the glass frit melting step may be then conducted. In this case, since the resin curing step is conducted first, the light-emitting element is protected by the cured resin adhesive to a certain extent. At this point, the light-emitting element is resistant to moisture or other infiltrates, and the glass frit melting step is then conducted. Thus, the atmosphere is not necessarily adjusted, for example, by filling the ambient atmosphere with a homogeneous gas to protect the light-emitting element in this glass frit melting step. For instance, the glass frit melting step can be conducted in the air. In this structure, the degree of care required to be taken during the manufacturing process can be significantly reduced in the glass frit melting step, which decreases the manufacturing cost.

Two types of adhesive elements, which are the glass frit and the resin adhesive, are used to bond the first substrate and the second substrate. This is significantly beneficial to provide the advantages of radiating heat generated from the light-emitting element and preventing the entry of moisture into the light-emitting element. However, this structure may require more efforts for manufacturing than the case of using only one type of adhesive. The advantage of improving ease of manufacturing including a decrease in manufacturing cost, which is mentioned in this structure or the structure described below, results in alleviating or solving such a problem. In other words, the advantage of improving ease of manufacturing contributes to providing the advantages of radiating heat and preventing the entry of moisture. Both the advantages interact each other.

In the method for manufacturing the light-emitting device according an aspect of the invention, the second application area may include an area that extends along a periphery of the second substrate. In this case, the entry of moisture into the light-emitting device can be more effectively prevented because the glass frit that has an advantage of protecting the entry of moisture is formed in a periphery of the second substrate, which is relatively far from the light-emitting element. In addition, if the external forms of the second substrate and the first substrate are the same, both the substrates are bonded together in their respective peripheries, which is preferable.

In the method for manufacturing the light-emitting device according to an aspect of the invention, the first application area may include an area of a central portion of the second substrate, the area being at a certain distance away from an inner edge of the second application area. In this case, since there is “a certain distance” between the first application area and the second application area, the possibility of a risk such as mixing of the resin adhesive with the glass frit paste during a manufacturing process can be reduced. Ease of manufacturing is improved in such a manner.

In the method for manufacturing the light-emitting device according to an aspect of the invention, the second substrate may have projections in areas corresponding to the first application area and the second application area. In this case, since the areas (hereinafter referred to as “projection areas” in SUMMARY) where the projections are formed correspond to the first application area and the second application area, ease of manufacturing is expected to be improved on the whole.

This is because the following advantages are provided: (i) when the glass frit paste is applied to the second substrate, the second application area is clearly defined in the case where one of the projections exists (“the second application area” in this case exactly corresponds to one of “the projection areas”), which makes it easier to control the total amount, the area or the like related to the application; (ii) since the resin adhesive is applied to the first application area on the first substrate and one of the projection areas faces the first application area, the resin adhesive receives a stronger force from the top face of one of the projection areas, which tends to achieve successful bonding; and (iii) the ridges of the projection areas or the like can be used to align the first substrate and the second substrate in the fourth step. Furthermore, such projections contribute to an increase in the volume of the second substrate compared with the case where the second substrate has a simple plate-like shape without the projections, whereby the second substrate further exhibits a function as a heat sink.

The method for manufacturing the light-emitting device according to an aspect of the invention may further include, before the fourth step, applying an adsorbent that adsorbs moisture to an area where the first application area and the second application area are not included. In this case, the entry of moisture or the like into the light-emitting element is prevented with more certainty. When the second substrate has the projections, the adsorbent is applied to the area (called a recessed area) other than the projection areas. In this state, since the adsorbent is applied to the area surrounded by the side walls of the projections, it is applied more precisely or easily in terms of alignment of the adsorbent or the like. More specifically, for example, the resin adhesive of the first application area is not easily brought into contact with or mixed with the adsorbent. In addition to the advantages described above, the structure including both “the projections” and “the adsorbent” provides its unique advantage.

In the method for manufacturing the light-emitting device according to an aspect of the invention, during the second step, the resin adhesive may be applied to the first application area while another resin adhesive may be applied to a third application area that surrounds the whole area including the area where the at least one light-emitting element is formed, the first application area, and the second application area. In this case, since the resin adhesive is applied to “the third application area”, the light-emitting element is protected from the entry of moisture or the like from the outside during a manufacturing process. If the glass frit melting step is conducted after the resin adhesive on the third application area is cured, the glass frit melting step is conducted, for example, in the air without taking any special measures to protect the light-emitting element.

This procedure becomes more preferable if the adsorbent described above is disposed. This is because the entry of moisture or the like into the adsorbent is prevented due to the resin adhesive on the third application area. In other words, the adsorbent remains unused during a manufacturing process. If the resin adhesive on the third application area does not exist, the adsorbent may adsorb a certain amount of moisture before the light-emitting device is completed. In a particular case, the adsorbent may be deteriorated to a certain extent before the finished light-emitting device is actually used. However, such a problem can be prevented in this structure.

In this structure, during the resin curing step, the resin adhesive and the other resin adhesive respectively applied to the first application area and the third application area may be cured at the same time. In this case, since the other resin adhesive and the resin adhesive are respectively applied to the third application area and to the first application area and then cured at the same time, the application of such resin adhesives does not affect a manufacturing process despite the fact that the advantage described above is provided. After the all steps specified in this specification are completed, the areas on the first and second substrates that correspond to the third application area may be removed by cutting or the like.

In the structure that requires “the third application area”, during the first step, the at least one light-emitting element may include a plurality of light-emitting elements that can be divided into a plurality of light-emitting element groups, the plurality of light-emitting elements being formed on the first substrate; the first application area may be constituted by a plurality of small areas that each corresponds to each of the plurality of light-emitting element groups and that each includes an area where the plurality of light-emitting elements are formed; and the second application area may be constituted by a plurality of small areas that each corresponds to each of the plurality of light-emitting element groups and that each surrounds the area where the plurality of light-emitting elements are formed. In this case, the plurality of light-emitting devices can be manufactured at a time from the first substrate or the second substrate with a large size. Since the third application area is arranged so as to surround the whole area where the plurality of light-emitting devices are formed as specified above, the advantages such as improving ease of manufacturing in the glass frit melting step, keeping the adsorbent unused, or the like are efficiently provided.

In the method for manufacturing the light-emitting device according to an aspect of the invention, during the first step, a driving-circuit-element thin film that drives the at least one light-emitting element may be formed on the first substrate; and, during the glass frit melting step, the glass frit paste may be melted by applying laser beams, the laser beams entering the second substrate and reaching the glass frit paste. In this case, the laser beams enter the second substrate where the driving-circuit-element thin film is not formed and directly reach the glass frit paste through the second substrate without being blocked by at least the driving-circuit-element thin film or being converted into thermal energy. That is, the energy of the laser beams is used for melting the glass frit paste without loss. However, the laser beams may enter the first substrate and reach the glass frit paste through the first substrate because the glass frit paste can also be melted in this manner.

### BRIEF DESCRIPTION OF THE DRAWINGS

FIG. 1 is a plan view of a light-emitting device according to an embodiment of the invention.

FIG. 2 is a sectional view taken along line II-II of FIG. 1.

FIG. 3 is a sectional view taken along line III-III of FIG. 1.

FIG. 4 is a sectional view (cover substrate: part 1) showing a method for manufacturing the light-emitting device of FIG. 1.

FIG. 5 is a sectional view (cover substrate: part 2) showing the method for manufacturing the light-emitting device of FIG. 1.

FIG. 6 is a sectional view (element substrate: part 1) showing the method for manufacturing the light-emitting device of FIG. 1.

FIG. 7 is a sectional view (element substrate: part 2) showing the method for manufacturing the light-emitting device of FIG. 1.

FIG. 8 is a sectional view (the lamination of the cover substrate and the element substrate) showing the method for manufacturing the light-emitting device of FIG. 1.

FIG. 9 is a sectional view showing a first comparative example (no first projection etc.) with relative to FIG. 3.

FIG. 10 is a sectional view showing a second comparative example (neither first nor second projection etc.) with relative to FIG. 3.

FIG. 11 is a sectional view showing a modification (the cover substrate without projections) according to the embodiment of the invention.

FIG. 12 is a sectional view showing a modification (providing an adsorbent to the structure of FIG. 11) according to the embodiment of the invention.

FIG. 13 is a plan view showing a modification (manufacturing a plurality of light-emitting devices at the same time and providing a resin adhesive that surrounds the light-emitting devices) according to the embodiment of the invention.

FIG. 14 is a plan view showing a modification (applying the embodiment of the invention to an image-displaying apparatus) according to the embodiment of the invention.

FIG. 15 is a perspective view partly showing a structure of an image-forming apparatus in which the light-emitting device is included as an optical head.

### DESCRIPTION OF EXEMPLARY EMBODIMENTS

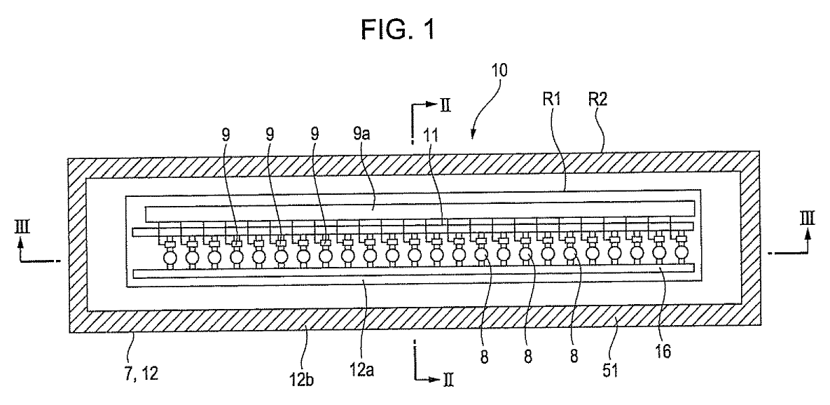

An embodiment according to the invention will now be described with reference to the drawings. Although the invention relates to a method for manufacturing a light-emitting device, a light-emitting device 10 itself manufactured by this method will be described first with reference to FIGS. 1 to 3, to make it easier to understand the whole description. In the drawings referred to below in addition to FIGS. 1 to 3, the scale of the components may be appropriately changed for ease of recognition.

As shown in FIGS. 1 to 3, the light-emitting device 10 according to this embodiment includes an element substrate 7 and a cover substrate 12. The element substrate 7 is a plate-like member having a substantially rectangular shape in plan view as shown in the drawings. The element substrate 7 is made of a light-transmissive material such as glass, quartz, or plastic.

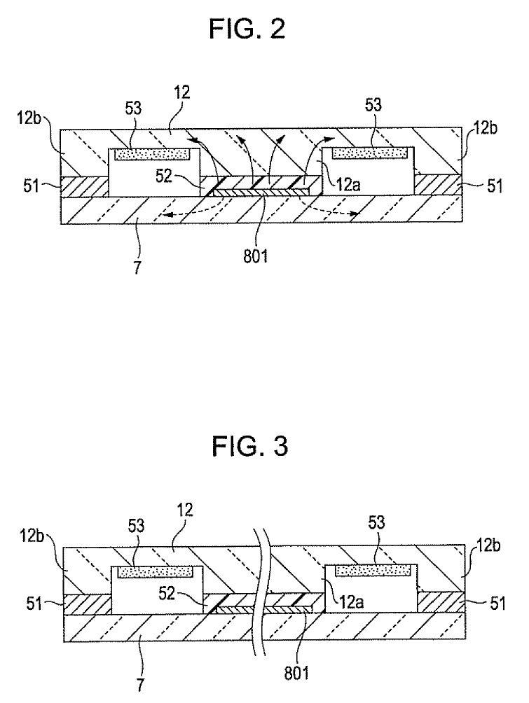

As shown in FIG. 1, organic EL elements 8, driving elements 9, a driving circuit 9a, and the like are disposed on the element substrate 7. Each of the organic EL elements (light-emitting elements) 8 has two electrodes that oppose each other and a light-emitting functional layer including at least an organic light-emitting sublayer between the two electrodes (both not shown). In FIGS. 2 and 3, these are stacked in a vertical direction of the drawings. A common line 16 is connected to one of the two electrodes and a data line 11 is connected to the other of the two electrodes through the driving element 9. The organic light-emitting sublayer included in the light-emitting functional layer is constituted by an organic EL material that emits light when electrons are combined with positive holes. The light-emitting functional layer may include some or all of an electron blocking sublayer, a hole injecting sublayer, a hole transporting sublayer, an electron transporting sublayer, an electron injecting sublayer, and a hole blocking sublayer, in addition to the organic light-emitting sublayer.

In this embodiment, the organic EL elements 8 are arranged in a line in the longitudinal direction of the element substrate 7. However, this arrangement is merely an example. For instance, the organic EL elements 8 may be arranged in a staggered configuration so as to be arranged on both sides of a line extending in the longitudinal direction of the element substrate 7 (“staggered configuration” means that when numbers are assigned to the organic EL elements from one end as 1, 2, 3, and so on, the odd-numbered elements are arranged on the lower side of FIG. 1 relative to the line while the even-numbered elements are arranged on the upper side).

Each of the driving elements 9 includes a switching element such as a thin film transistor (TET) or a thin film diode (TFD). The driving elements 9 arranged between the organic EL elements 8 and the data line 11 control whether a current is allowed to flow. The driving circuit 9a controls ON and OFF of the switching elements included in the driving elements 9. When a TFT is adopted as the switching element, the data line 11 is connected to the source region and the driving circuit 9a is connected to the gate electrode.

Through the function of the driving circuit 9a and the driving elements 9, a current is fed to the light-emitting functional layer from one of the two electrodes that constitute each of the organic EL elements 8, whereby the organic EL elements 8 emit light. Alternatively, a current is not fed to the light-emitting functional layer from one of the two electrodes, whereby the organic EL elements 8 do not emit light. Note that when the organic EL elements 8 emit light, the organic EL elements 8 generate heat.

In addition to the components described above, a metal thin film or the like used for various input/output terminals or the like is formed on the element substrate 7 so as to extend along one side of the element substrate 7 and extend in the direction perpendicular to the one side (not shown).

The driving elements 9, the driving circuit 9a, the data line 11, the common line 16, the metal thin film used for the terminals, and the like are all included in the concept of “a driving-circuit-element thin film” in this specification. In FIGS. 2 and 3, these various components are drawn in a simplified manner so that the drawings can be clearly understood. In other words, a rectangular component denoted by reference numeral 801 represents “the driving-circuit-element thin film” (the metal thin film is not represented by the rectangular component because it is formed along the periphery of the element substrate 7). The rectangular component denoted by reference numeral 801 in FIGS. 2 and 3 is intended to include the organic EL elements 8 in addition to various components such as the driving elements 9. This is simply referred to as “a circuit-element thin film 801”, hereinafter.

The cover substrate 12 is also a plate-like member having a substantially rectangular shape in plan view, similar to the element substrate 7. In this embodiment, the area of the cover substrate 12 in plan view is the same as that of the element substrate 7. As shown in FIGS. 2 and 3, however, the sectional shape of the cover substrate 12 is different from that of the element substrate 7. That is, the cover substrate 12 partly includes a first projection 12a and a second projection 12b.

As is evident from FIGS. 1 to 3, the first projection 12a is positioned in the central portion of the cover substrate 12, not in the periphery and its adjacent area in plan view. The shape of the first projection 12a in plan view is a rectangle. The first projection 12a is formed so as to cover the area where the organic EL elements 8 are formed or, particularly in this embodiment, the area where the circuit-element thin film 801 is formed.

The second projection 12b extends along the periphery of the cover substrate 12 in plan view. Therefore, the second projection 12b forms a closed rectangle when viewed in plan. Although there is no difference between the second projection 12b and first projection 12a in that they are both “rectangles”, it is clear from the drawings that the rectangle of the former is empty whereas that of the latter is solid. The second projection 12b extends so as to surround the area where the organic EL elements 8 are formed or, particularly in this embodiment, the area where the circuit-element thin film 801 is formed.

As shown in FIGS. 1 to 3r the element substrate 7 and the cover substrate 12 described above are laminated so as to face each other. Specifically, the element substrate 7 and the cover substrate 12 are laminated such that the surface of the element substrate 7 where the circuit-element thin film 801 is formed faces the cover substrate 12 and the first projection 12a and the second projection 12b of the cover substrate 12 face the element substrate 7.

The element substrate 7 and the cover substrate 12 are bonded together using a resin adhesive 52 that is arranged in the area corresponding to the area where the first projection 12a is formed and using a glass frit 51 that is arranged in the area corresponding to the area where the second projection 12b is formed. In addition, an adsorbent 53 is arranged in the area corresponding to the area where the first projection 12a and the second projection 12b are not formed. As is clear from FIGS. 2 and 3, since the area is surrounded by (the side walls of) the first projection 12a and the second projection 12b, the area can be called a recessed area when their relative positions are considered. The adsorbent 53 can be stably arranged in the area because the area is recessed.

The light-emitting device 10 preferably has, for example, a length (the length in a horizontal direction of FIG. 1) of 330 to 350 mm, a width (the length in a vertical direction of FIG. 1) of 10 to 30 mm, and a thickness (the length in a vertical direction of FIGS. 2 and 3) of 1 to 5 mm. This example of a light-emitting device can support a recording material (a transfer medium) whose size is “A3”.

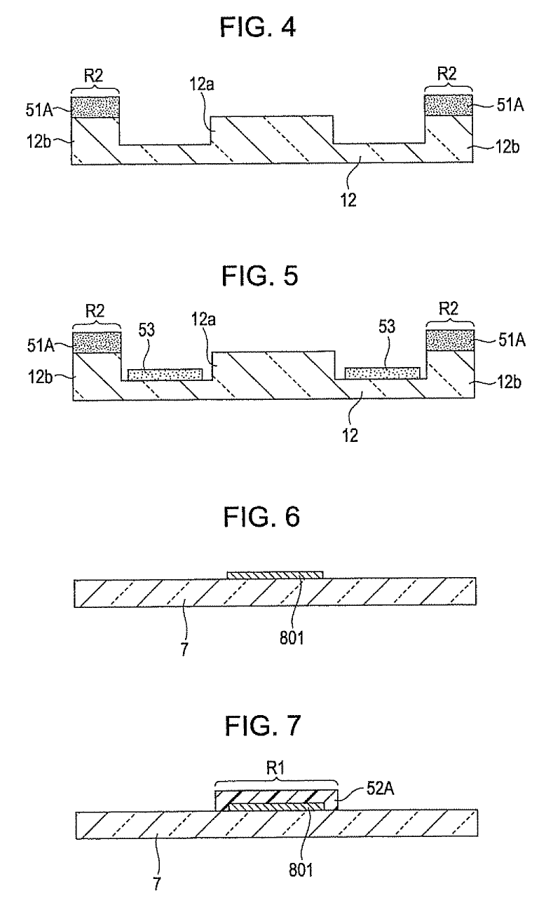

A method for manufacturing the light-emitting device 10 having the structure described above will now be described with reference to FIGS. 4 to B. As shown in FIG. 4, the cover substrate 12 in which the first projection 12a and the second projection 12b are formed by, for example, cutting in advance, is prepared, and a glass frit paste 51A is applied to the top face of the second projection 12b (the top face (not shown) is turned upward in FIG. 4).

The glass frit paste 51A may be a mixture of a glass frit mainly made of zinc oxide (ZnO), bismuth trioxide (Bi₂O₃), phosphorus pentoxide (P₂O₅), and the like; resin fine particles of polyethylene, urethane, acrylic, or the like; a high-melting point filler such as alumina (Al₂O₃) or silica (SiO₂); a solvent such as terpineol; and the like. Examples of the application method include a dispenser method and a screen printing method. The thickness of the application is preferably about 5 to 40 μm. In FIG. 4, after such a glass frit paste is applied, the cover substrate 12 is calcined, for example, at about 400° C. for 20 minutes.

As described above or as shown in FIG. 4 or 1, the second projection 12b or the top face extends along the periphery of the cover substrate 12. The area where the glass frit paste 51A is applied is hereinafter referred to as “a second application area R2” for convenience of description.

In this regard, various parameters related to the application of the glass frit paste 51A such as the total amount, the area, or the thickness are easily controlled when the glass frit paste 51A is applied to the second application area R2 where the top face of the second projection 12b continuously extends. This is because the area of the second application area R2 is determined.

As shown in FIG. 5, the adsorbent 53 in a liquid or paste form is applied to the area where the first projection 12a and the second projection 12b of the cover substrate 12 are not formed. Examples of the application method include a dispenser method and the like. This application step is preferably conducted in a dry nitrogen atmosphere to prevent the degradation of the adsorbent 53. The adsorbent 53 preferably includes a suitable metal complex compound or a suitable organic metal compound. When the adsorbent 53 is applied, a solution in which the organic metal compound or the like is dispersed can be used.

As described above, the area where the adsorbent 53 is applied can be called a recessed area when the relative positions of the first projection 12a and the second projection 12b are considered. This means that the adsorbent 53 can be applied to a predetermined area on the cover substrate 12 naturally or without taking any special measures, which improves ease of manufacturing.

As shown in FIG. 6, the circuit-element thin film 801 is formed on the element substrate 7 prepared separately from the cover substrate 12. The circuit-element thin film 801 includes the organic EL elements 8, the driving elements 9, the driving circuit 9a, and the like as described above. Thus, when the circuit-element thin film 801 is formed, these various components are obviously formed and the individual parts included in each of the various components are also formed. For example, since the organic EL elements 8 include parts such as the two electrodes and the light-emitting functional layer as described above, these parts are successively or suitably formed when the circuit-element thin film 801 is formed. Various semiconductor manufacturing technologies such as a vapor deposition method, a sputtering method, or a photolithography method can be used to form the circuit-element thin film 801.

As shown in FIG. 7, a resin adhesive 52A to be cured (hereinafter referred to as “a raw adhesive 52A”) is applied to the element substrate 7 so as to cover the circuits element thin film 801 manufactured in the previous step. The raw adhesive 52A may be an ultraviolet curable resin or a thermosetting resin. Examples of the application method include a dispenser method and a screen printing method.

This application step is also preferably conducted in a dry nitrogen atmosphere as with the adsorbent 53 described above. However, the dry nitrogen atmosphere in this step is used to mainly protect the organic EL elements 8 included in the circuit-element thin film 801 from moisture or the like. In the case where a protection film or the like made of a material such as SiON or SiN that covers the organic EL elements 8 is formed, the application step of the raw adhesive 52A shown in FIG. 7 is not necessarily conducted in a dry nitrogen atmosphere.

As described above or as shown in FIG. 7 or 1, the area where the raw adhesive 52A is applied corresponds to the area where the first projection 12a is formed on the cover substrate 12 or to the central portion of the element substrate 7. The area where the raw adhesive 52A is applied is hereinafter referred to as “a first application area R1” for convenience of description.

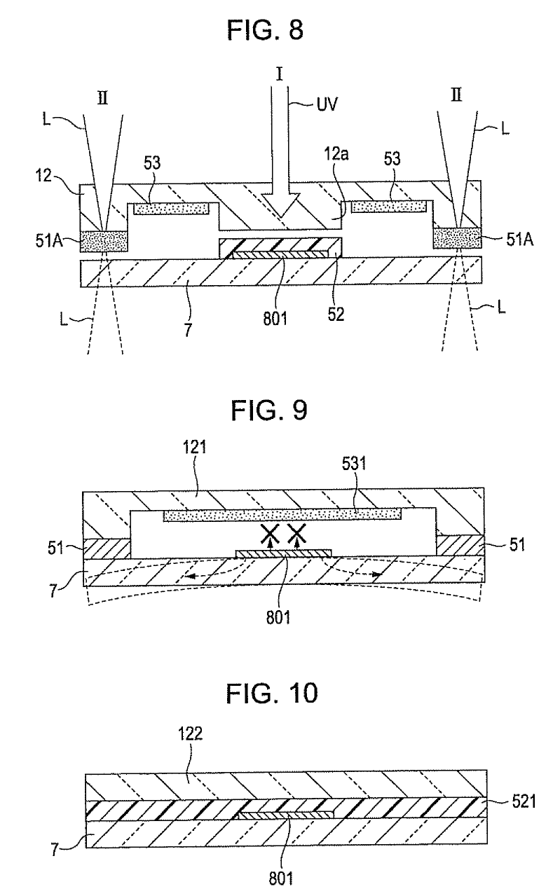

As shown in FIG. 8, the cover substrate 12 subjected to the processes shown in FIGS. 4 and 5 and the element substrate 7 subjected to the processes shown in FIGS. 6 and 7 are laminated together. As is evident from the drawing, they are laminated such that the raw adhesive 52A faces the top face of the first projection 12a and the outer edges of both the substrates 7 and 12 are substantially completely aligned when viewed in plan. In this case, since the ridge of the first projection 12a, the ridge of the second projection 12b, or the like is relatively visible or is suitable for pattern recognition processing when image processing is conducted, such a ridge can be preferably used to align both the substrates 7 and 12.

In this state, the raw adhesive 52A is firstly cured and the glass frit paste 51A is secondly melted. In the drawing, Roman numeral “I” printed next to reference symbol UV and Roman numeral “II” printed next to reference symbol L denote the order of such steps. Reference symbols “UV” and “L” denote “ultraviolet rays” and “laser beams”, respectively.

The method for curing the raw adhesive 52A varies depending on the material used as the raw adhesive 52A. In the case where the raw adhesive 52A is made of an ultraviolet curable resin, for example, ultraviolet rays UV are used as shown in FIG. 8. The ultraviolet rays UV enter the cover substrate 12 and reach the raw adhesive 52A through the cover substrate 12. Alternatively, in the case where the raw adhesive 52A is made of a thermosetting resin, for example, the raw adhesive 52A is heated with an appropriate heater placed above the upper side of the cover substrate 12 in the drawing.

In either method, the raw adhesive 52A is cured to form the resin adhesive 52, whereby the element substrate 7 and the cover substrate 12 are bonded together. After this point, that is, after the raw adhesive 52A is cured, the circuit-element thin film 801, particularly the organic EL elements 8 included therein, is sealed with the cured resin adhesive 52, which protects the circuit-element thin film 801 from the entry of moisture or the like from the outside.

Regardless the material used as the raw adhesive 52A, this curing step is preferably conducted in a dry nitrogen atmosphere as with the application step of the raw adhesive 52A. However, the dry nitrogen atmosphere in this step is also used to mainly protect the organic EL elements 8 as with the application step of the raw adhesive 52A. In the case where a protection film or the like that covers the organic EL elements 8 is formed, the curing step is not necessarily conducted in a dry nitrogen atmosphere.

In this curing step, a certain force is preferably applied between the element substrate 7 and the cover substrate 12, In other words, the raw adhesive 52A is cured while being pressurized. Since the cover substrate 12 of this embodiment has the first projection 12a as described above, a relatively strong force tends to be applied between the top face and the element substrate 7 (that is, the raw adhesive 52A). That is to say, a weak force applied to the entire device means a strong force applied to the raw adhesive 52A. In summary, even a weak force can achieve successful adhesion due to the presence of the first projection 12a.

In the melting step of the glass frit paste 51A, suitable laser beams L are used as shown in FIG. 8. The laser beams L enter the cover substrate 12 and reach the glass frit paste 51A through the cover substrate 12. The laser beams L are then converted into thermal energy, which melts the glass frit paste 51A. When the irradiation of the laser beams L is stopped, the glass frit paste 51A rapidly cools and solidifies. The glass frit paste 51A solidifies to form the glass frit 51, whereby the element substrate 7 and the cover substrate 12 are bonded together.

Special consideration is not necessarily given to the atmosphere in this melting step. For example, this step can be conducted in the air. This is because, as described above, the organic EL elements 8 have already been protected from the entry of moisture or the like to some extent due to the cured resin adhesive 52. This improves ease of handling and ease of manufacturing in terms of the manufacturing method as a whole.

In this melting step, the laser beams L preferably enter the cover substrate 12 and reach the glass frit paste 51A through the cover substrate 12. This is because, as described above, the metal thin film or the like (not shown in FIG. 8 and the metal thin film is included in the concept of “a driving-circuit-element thin film” in this specification) used for various input/output terminals or the like is formed on the element substrate 7 so as to extend along one side of the element substrate 7 and extend in the direction perpendicular to the one side. If the laser beams L enter the element substrate 7 and reach the glass frit paste 51A through the element substrate 7, they would be partly converted into thermal energy due to the metal thin film or the like or they would be simply blocked. If the laser beams L enter the cover substrate 12 and reach the glass frit paste 51A through the cover substrate 12, such problems do not occur and the energy of the laser beams L is used for melting the glass frit paste 51A without loss. However, the laser beams L may enter the element substrate 7 and reach the glass frit paste 51A through the element substrate 7 in an embodiment of the invention because the glass frit paste 51A can also be melted in this manner (refer to broken lines of FIG. 8).

Up to this point, the complete form of the light-emitting device 10 shown in FIG. 2 has been obtained.

The light-emitting device 10 of this embodiment or the manufacturing method thereof provides the following advantages.

(1)

The complete form of the light-emitting device 10 manufactured by the method described above provides the following advantages. First, the circuit-element thin film 801 including the organic EL elements 8 is sealed within the cured resin adhesive 52. In addition, since the resin adhesive 52 is arranged in the first application area R1 corresponding to the area where the top face of the first projection 12a extends or the area where the first projection 12a is formed, the resin adhesive 52 is in close contact with the first projection 12a. Therefore, the heat generated from the organic EL elements B can be conducted away, as indicated by solid-line arrows of FIG. 2, in the order of the resin adhesive 52, the first projection 12a, and the body of the cover substrate 12 (the portion where the first projection 12a and the second projection 12b are removed from the cover substrate 12). The heat can also be obviously conducted to the element substrate 7 side as indicated by broken-line arrows of FIG. 2. In the light-emitting device 10 of this embodiment, the heat generated from the organic EL elements 8 can be significantly effectively radiated.

The first projection 12a also provides another advantage, which is different from the advantage related to, for example, the manufacturing method in which a strong force is applied to the raw adhesive 52A. As is evident from FIG. 2, the first projection 12a acts to maintain a large distance between the organic EL elements 8 and the boundary of the cover substrate 12 with the outside (assume the cover substrate without the first projection 12a and having the same thickness as the body of the cover substrate 12 shown in FIG. 2). This further increases a temperature gradient between the organic EL elements 8 and the boundary of the cover substrate 12 with the outside.

The first projection 12a increases the overall volume of the cover substrate 12 without unnecessarily increasing the volume of the body of the cover substrate 12 (the same thing can be said for the second projection 12b in this regard). Therefore, the first projection 12a works so as to improve the function of the cover substrate 12 as a heat sink. In this embodiment, the advantage concerning the heat radiation described above can be effectively provided.

In the light-emitting device 10 of this embodiment, the organic EL elements 8 are protected from moisture, oxygen, or the like that exists outside, firstly by the glass frit 51 extending so as to surround the area where the organic EL elements 8 are formed and secondly by the resin adhesive 52. In particular, the glass frit 51 of this embodiment exhibits an even higher effect of preventing the entry of moisture than the resin adhesive 52. This comes from the difference in characteristics of these materials between the “glass” frit 51 and the ‘resin’ adhesive 52. Therefore, for example, if a structure in which the glass frit 51 in FIG. 2 is replaced with a resin adhesive is assumed, the effect of preventing the entry of moisture would be obviously inferior compared with the embodiment shown in FIG. 2. Furthermore, even if moisture enters between the element substrate 7 and the cover substrate 12 despite the presence of the glass frit 51, the moisture is captured with the adsorbent 53. In the light-emitting device 10 of this embodiment, the entry of moisture or the like into the organic EL elements 8 can be suppressed to a maximum extent.

Such an advantage is highlighted by comparison with comparative examples. Compared with FIG. 2, FIG. 9 illustrates a structure in which the first projection 12a that would be extending in the central portion of the cover substrate 12 does not exist. The light-emitting device shown in FIG. 9 includes a cover substrate 121 having a uniformly flat surface except for the second projection 12b extending along the periphery and having an adsorbent 531 disposed on the flat surface.

In this case, as is clear from the comparison of FIG. 9 with FIG. 2, there is no thermal conduction path through the first projection 12a in FIG. 9 (refer to x marks of the drawing). Thermal conduction occurs only through the element substrate 7 (refer to broken-line arrows of the drawing). Thus, the heat generated from the organic EL elements 8 tends to internally remain, which may adversely affect the light-emitting characteristics of the organic EL elements 8. Moreover, since the thermal conduction occurs only through the element substrate 7, deformation or the like of the element substrate 7 may easily occur (the drawing rather exaggeratedly shows an example of “warpage”).

Compared with FIG. 2, FIG. 10 illustrates a structure in which both the first projection 12a and the second projection 12b do not exist. The light-emitting device shown in FIG. 10 includes a cover substrate 122 having a uniformly flat surface on the inner side thereof and having a resin adhesive 521 disposed so as to face the whole flat surface.

In this case, unlike the case of FIG. 9, thermal conduction paths exist in all directions from the organic EL elements 8. In other words, the heat generated from the organic EL elements 8 can be conducted through the element substrate 7 and the cover substrate 122. However, since the element substrate 7 and the cover substrate 122 are bonded together using the resin adhesive 521 in this comparative example but not the glass frit 51 that exhibits a higher sealing performance than the resin adhesive 521, there may be a risk of the entry of moisture into the organic EL elements 8.

In the comparative example shown in FIG. 10, it is quite difficult to use a glass frit for bonding the element substrate 7 and the cover substrate 122. This is because a glass frit paste would be applied so as to inevitably cover the organic EL elements 8 (and the entire circuit-element thin film 801 as well), whereby the melting step of the glass frit would not be able to be conducted (or the laser beams L would not be able to be applied) in the area where the organic EL elements 8 are formed and the area surrounded by the organic EL elements 8.

From the comparison described above, the superiority of the light-emitting device 10 of this embodiment can be recognized.

In this embodiment, the following advantages are also provided in addition to the advantages described in (1) (the advantages described above are also included).

(2)

Since the raw adhesive 52A is cured first and the glass frit paste 51A is then melted in this embodiment, the degree of care required to be taken during the manufacturing process can be significantly reduced in the melting step. Thus, the manufacturing cost can be decreased.

(3)

The first projection 12a and the second projection 12b of the cover substrate 12 have various advantages during the manufacturing process of the light-emitting device 10: (i) various parameters related to the application of the glass frit paste 51A such as the total amount, the area, or the thickness are easily controlled because the second projection 12b is formed; (ii) a strong force can be applied to the raw adhesive 52A because the first projection 12a is formed, whereby the element substrate 7 and the cover substrate 12 are successfully bonded; (iii) the ridge of the first projection 12a, the ridge of the second projection 12b, and the like can be used to align the element substrate 7 and the cover substrate 12; and (iv) although the first projection 12a and the second projection 12b on the cover substrate 12 form a recessed area therebetween, the recessed area improves ease of manufacturing in the application step of the adsorbent 53.

(4)

In this embodiment, the laser beams L enter the cover substrate 12 and reach the glass frit paste 51A through the cover substrate 12 without being blocked by the metal thin film or the like used for the various terminals in the melting step of the glass frit paste 51A. Thus, the glass frit paste 51A is significantly effectively melted.

Although the light-emitting device according to an embodiment of the invention has been described, the light-emitting device is not limited to the embodiment and various modifications can be made.

### (A)

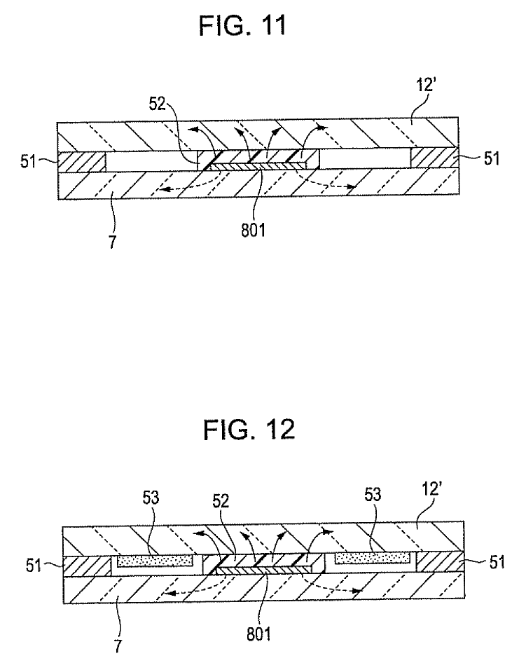

In the light-emitting device 10 according to the embodiment described above, the cover substrate 12 includes the first projection 12a and the second projection 12b, but not limited to this. As shown in FIG. 11, a cover substrate 12′ having no projection may be used. However, the cover substrate 12′ and the element substrate 7 need to be bonded using two types of adhesive elements, which are the resin adhesive 52 applied so as to cover the circuit-element thin film 801 and the glass frit 51 extending along the periphery of the cover substrate 12′ and the element substrate 7 (this point is different from the case of FIG. 10).

In this structure, it is clear that essentially the same advantage as in the embodiment described above can be provided as indicated by solid-line and broken-line arrows of the drawing. In addition, an effort that is necessary to form projections can be saved. However, since the first projection 12a and the second projection 12b provide various advantages as described in (i) to (iv), the structure shown in FIG. 11 is not necessarily superior to the embodiment described above. Either this structure or the embodiment should be selected in accordance with various circumstances. Note that even in the structure shown in FIG. 11, the adsorbent 53 can be disposed as shown in FIG. 12.

### (B)

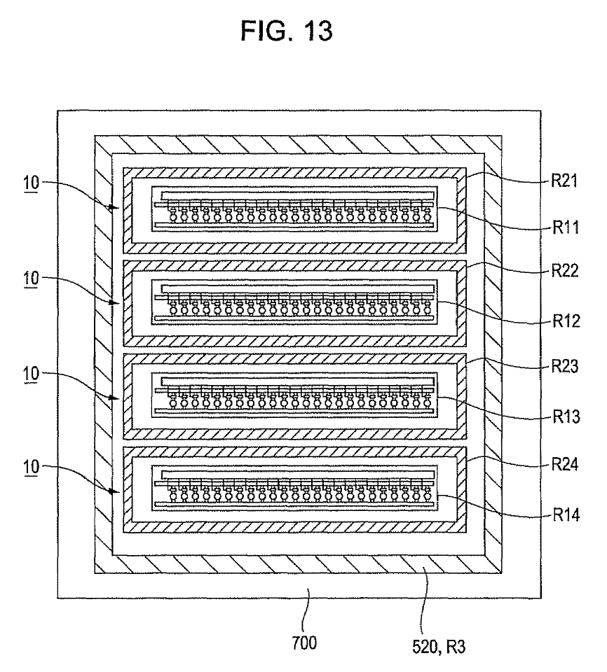

In the embodiment described above, manufacturing of a single light-emitting device 10 has been described with reference to FIGS. 4 to 8. However, the invention is not limited to this. In a practical manner, for example, a plurality of light-emitting devices 10 are usually formed together on an element substrate 700 with a large size as shown in FIG. 13. Although four light-emitting devices 10 are formed together in FIG. 13, the number of light-emitting devices 10 is not limited.

As shown in FIG. 13, a resin adhesive 520 is more preferably applied so as to surround the area where the plurality of light-emitting devices 10 are formed. The resin adhesive 520 is processed when the resin adhesive 52 of the embodiment described above is processed. In other words, when the raw adhesive 52A described with reference to FIG. 7 is applied, a raw adhesive to be the resin adhesive 520 is also applied. When the raw adhesive 52A is cured, the raw adhesive to be the resin adhesive 520 is also cured. This means that forming the resin adhesive 520 does not increase extra manufacturing costs.

Such a resin adhesive 520 provides the following advantages. First, since the resin adhesive 520 surrounds all of the plurality of light-emitting devices 10 as shown in FIG. 13, all of the organic EL elements 8 included in these light-emitting devices 10 can be effectively protected from moisture during a manufacturing process. Second, the adsorbent 53 included in these light-emitting devices 10 can be protected from moisture due to the same reason. This is significantly effective to prevent the adsorbent 53 from being deteriorated to a certain extent before the finished light-emitting devices 10 are actually used.

In FIG. 13, all of the organic EL elements 8 included in one of the plurality of light-emitting devices 10 are one example of a single “light-emitting element group” in this specification. Each of the areas represented by reference numerals R11, R12, R13, and R14 is one example of “a small area” in this specification that constitutes “the first application area”. Each of the areas represented by reference numerals R21, R22, R23, and R24 is one example of “a small area” in this specification that constitutes “the second application area”.

### (C)

The light-emitting device 10 of the embodiment described above has a structure in which organic EL elements 8 are arranged in a line, thereby being preferably used for a printer head. However, the invention is not limited to this.

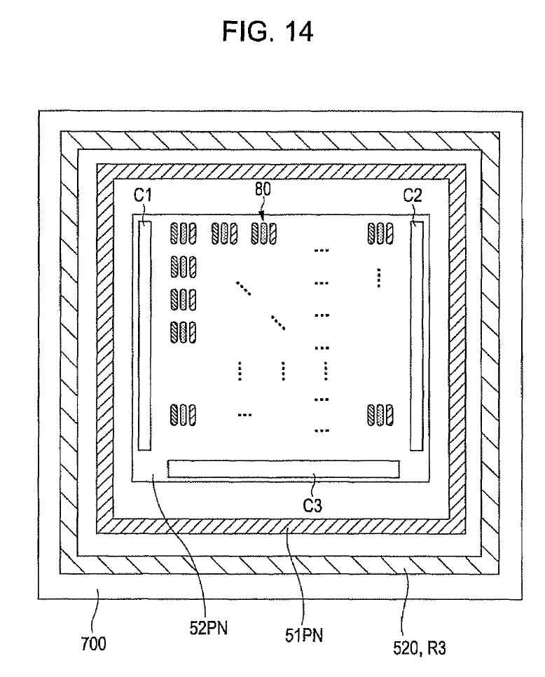

As shown in FIG. 14, for example, the embodiment of the invention can be applied to an image-displaying apparatus for displaying a desired image by arranging organic EL elements 80 on the element substrate 700 in a matrix pattern. In FIG. 14, reference numerals 51PN and 52PN respectively denote the application area of a glass frit and the application area of a resin adhesive, which are one example of “the second application area” and one example of “the first application area” in this specification. Furthermore, an adsorbent (not shown) may be disposed in the frame-shaped area formed between the first application area and the second application area as with the embodiment described above. In the structure shown in FIG. 14, the resin adhesive 520 can be obviously applied.

In FIG. 14, the components denoted by reference numerals C1 to C3 are driving circuits for driving the organic EL elements 80. The driving circuits C1 to C3 are assumed to substantially correspond to the circuit-element thin film 801 of the embodiment described above. Each of the driving circuits C1 to C3 is also one example of “the driving-circuit-element thin film” in this specification.

In FIG. 14, a single “light-emitting device” is assumed to be formed on the element substrate 700 with a large size. In other words, the light-emitting device substantially corresponds to “the image-displaying apparatus”.

The advantages obtained from the resin adhesive 520 are also obviously provided in the structure shown in FIG. 14. Even if a single light-emitting device 10 is manufactured on the element substrate 700 with a large size, such advantages are also theoretically provided in the case where a resin adhesive is formed so as to surround the single light-emitting device 10. Although it is difficult to actually utilize this structure in terms of manufacturing efficiency or the like, this structure is also not eliminated.

### APPLICABLE EXAMPLE

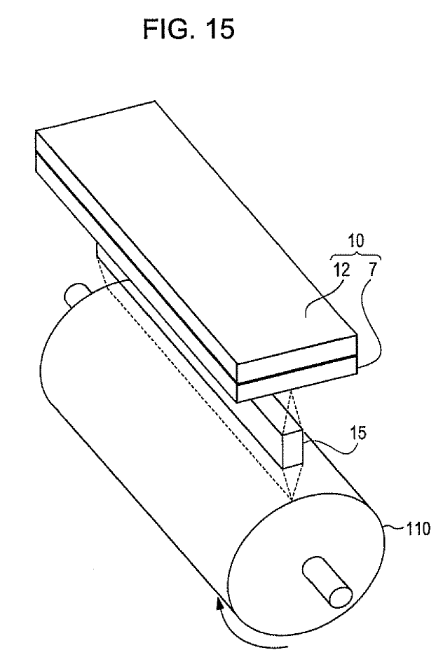

FIG. 15 is a perspective view partly showing a structure of an image-forming apparatus in which the light-emitting device 10 of the embodiment described above is used as an optical head (light-emitting device). The image-forming apparatus includes the light-emitting device 10, a converging lens array 15, and a photosensitive drum 110.

The light-emitting device 10 includes a plurality of organic EL elements (light-emitting elements) arranged in a line. Each of the organic EL elements emits light in the downward direction of FIG. 15 (refer to broken lines in the drawing), and the light enters the converging lens array 15 described below.

The converging lens array 15, which is disposed between the light-emitting device 10 and the photosensitive drum 110, includes many gradient index lenses arranged in an array, with its individual optical axes being directed to the light-emitting device 10. The light emitted from each of the organic EL elements included in the light-emitting device 10 passes through each of the gradient index lenses within the converging lens array 15 and then reaches the external surface of the photosensitive drum 110.

For example, SELFOC® Lens Array (SLA) available from Nippon Sheet Glass Co., Ltd. can be used as the converging lens array 15. With this lens array, the light emitted from the light-emitting device 10 forms an erect equal-magnification image on the photosensitive drum 110.

The photosensitive drum 110 has a substantially cylindrical shape, and a rotating shaft extends along a central axis of the photosensitive drum 110. The photosensitive drum 110 rotates around the rotating shaft in a subscanning direction in which a recording material (a transfer medium) is transported (refer to an arrow in the drawing). The rotating shaft extends in a main scanning direction.

The photosensitive drum 110 and the light-emitting device 10 are controlled such that there is a certain relationship between the rotating timing of the photosensitive drum 110 and the light-emitting timing of each of the organic EL elements included in the light-emitting device 10. In the main scanning direction, for example, each of the organic EL elements is controlled to emit or not to emit light in accordance with a light and dark pattern in one line of an image to be formed. In the subscanning direction, on the other hand, the rotation of the photosensitive drum 110 is controlled such that after the photosensitizing process for one line of an image is completed, the photosensitive drum 110 rotates certain degrees. Thus, a latent image (electrostatic latent image) is formed on the external surface of the photosensitive drum 110 in accordance with a desired image.

The entire disclosure of Japanese Patent Application No. 2008-039839, filed Feb. 21, 2008 is expressly incorporated by reference herein.

What is claimed is:

1. A method for manufacturing a light-emitting device comprising:
a first step of forming at least one light-emitting element on a first substrate;
a second step of applying a resin adhesive to a first application area that includes an area where the at least one light-emitting element is formed, so as to cover the at least one light-emitting element;
a third step of applying a glass frit paste on a surface of the first substrate where the at least one light-emitting element is formed or on a second substrate and also to a second application area that surrounds the area where the at least one light-emitting element is formed;
a fourth step of laminating the first substrate and the second substrate;
a resin curing step of curing the resin adhesive to bond the first substrate and the second substrate in the first application area and to seal the at least one light-emitting element from an outside; and
a glass frit melting step of melting the glass frit paste to bond the first substrate and the second substrate in the second application area.

2. The method for manufacturing a light-emitting device according to claim 1, wherein after the fourth step, the resin curing step is conducted and the glass frit melting step is then conducted.

3. The method for manufacturing a light-emitting device according to claim 1, wherein the second application area includes an area that extends along a periphery of the second substrate.

4. The method for manufacturing a light-emitting device according to claim 1, wherein the first application area includes an area of a central portion of the second substrate, the area being at a certain distance away from an inner edge of the second application area.

5. The method for manufacturing a light-emitting device according to claim 4, wherein the second substrate has projections in areas corresponding to the first application area and the second application area.

6. The method for manufacturing a light-emitting device according to claim 1, further comprising, before the fourth step, applying an adsorbent that adsorbs moisture to an area where the first application area and the second application area are not included.

7. The method for manufacturing a light-emitting device according to claim 1, wherein, in the second step, the resin adhesive is applied to the first application area while another resin adhesive is applied to a third application area that surrounds a whole area including the area where the at least one light-emitting element is formed, the first application area, and the second application area.

8. The method for manufacturing a light-emitting device according to claim 7, wherein, in the resin curing step, the resin adhesive and the other resin adhesive respectively applied to the first application area and the third application area are cured at the same time.

9. The method for manufacturing a light-emitting device according to claim 7,
wherein, in the first step, the at least one light-emitting element includes a plurality of light-emitting elements that can be divided into a plurality of light-emitting element groups, the plurality of light-emitting elements being formed on the first substrate;
wherein the first application area is constituted by a plurality of small areas that each corresponds to each of the plurality of light-emitting element groups and that each includes an area where the plurality of light-emitting elements are formed; and
wherein the second application area is constituted by a plurality of small areas that each corresponds to each of the plurality of light-emitting element groups and that each surrounds the area where the plurality of light-emitting elements are formed.

10. The method for manufacturing a light-emitting device according to claim 1,
wherein, in the first step, a driving-circuit-element thin film that drives the at least one light-emitting element is formed on the first substrate; and
wherein, in the glass frit melting step, the glass frit paste is melted by applying laser beams, the laser beams entering the second substrate and reaching the glass frit paste.
